(19) United States
(12) Patent Application Publication
(10) Pub. No.: US 2026/0133248 A1
(43) Pub. Date: May 14, 2026

(54) ELECTRICAL STRESS DETECTION CIRCUITRY FOR A SEMICONDUCTOR PACKAGE

(71) Applicant: Sandisk Technologies, Inc., Milpitas, CA (US)

(72) Inventors: Raghavan Nagarajan, Bengaluru (IN); Darshvir Singh Grewal, Bengaluru (IN); Balaji G K, Hosur (IN)

(21) Appl. No.: 18/943,157

(22) Filed: Nov. 11, 2024

(51) Int. Cl. G01R 31/28; G01R 19/165

(52) U.S. Cl. CPC G01R 31/2884; G01R 19/1659; G01R 31/2896

(57) ABSTRACT

A semiconductor package includes electrical stress detection circuitry for determining whether one or more signal lines of the semiconductor package that extend between a controller and one or more semiconductor dies are subjected to electrical stresses, such as overshoot and/or undershoot. The electrical stress detection circuitry is electrically coupled to the one or more signal lines and receives a test voltage from the controller. When the test voltage is received, the electrical stress detection circuitry compares the test voltage to a configurable threshold voltage, which is also received from the controller. When the comparison between the test voltage and the threshold voltage is complete, the electrical stress detection circuitry provides feedback to the controller. The feedback indicates whether the test voltage exceeds the threshold voltage.

### BACKGROUND

Integrated circuits and semiconductor packages are often subjected to various electrical stresses that can reduce their lifespan. Some of these electrical stresses include phenomenon known as overshoot and undershoot. An overshoot occurs when a voltage of a signal exceeds a desired amplitude. Likewise, an undershoot occurs when the voltage of a signal falls below a desired amplitude.

In current implementations, the amplitude of a signal is detected at a test point or test pad of the semiconductor package. However, the test point is typically located far away from input/output pads of one or more semiconductor dies of the semiconductor package. For example, the test point is provided on a printed circuit board (PCB) or substrate outside of packaging that surrounds or encapsulates the one or more semiconductor dies. As a result, a measurement of the signal may be inaccurate and overshoot and/or undershoot may go undetected.

As semiconductor packages continue to evolve and become more complex, this problem becomes more exacerbated. For example, if a semiconductor package has multiple semiconductor dies stacked on top of one another, a single test point is used to check the signal that is transmitted to each semiconductor die-regardless of whether the semiconductor die is at the top of the stack or the bottom of the stack. However, the single test point does not accurately measure of the amplitude of the signal that is transmitted to each semiconductor die in the stack.

Accordingly, it would be beneficial to accurately test signals for overshoot and undershoot regardless of a position of a semiconductor die in the semiconductor package and/or regardless of a location of the semiconductor die in the stack of semiconductor dies.

### SUMMARY

The present disclosure describes electrical stress detection circuitry for a semiconductor package. The electrical stress detection circuitry, also referred to a swing level detector, is electrically coupled to one or more input/output lines, or signal lines, of a semiconductor package. For example, the electrical stress detection circuitry is coupled to one or more input/outlines that extend between a controller associated with the semiconductor package and one or more semiconductor dies of the semiconductor package. The electrical stress detection circuitry is located proximate to the semiconductor dies and senses a signal that is transmitted from the controller.

When the signal is received, the electrical stress detection circuitry compares a voltage of the received signal to a configurable threshold voltage. In an example, the configurable threshold voltage is a first threshold voltage associated with an overshoot value. In another example, the configurable threshold voltage is a second threshold voltage associated with an undershoot value. When the comparison is complete, the electrical stress detection circuitry provides feedback to the controller. The feedback indicates whether the voltage of the received signal exceeds one or more of the thresholds.

Accordingly, examples of the present disclosure describe a method for measuring electrical stress of a semiconductor package. In an example, the method includes transmitting a test voltage to a swing level detector associated with a stack of semiconductor dies. The swing level detector is electrically coupled to a plurality of signal lines associated with the stack of semiconductor dies. A controller associated with the semiconductor package causes the swing level detector to compare the test voltage to at least one of a first threshold voltage associated with an overshoot value and a second threshold voltage associated with an undershoot value. In an example, the comparison is performed on a particular signal line of the plurality of signal lines. A result of the comparison is also received.

Other examples describe a semiconductor package that includes a controller, a stack of semiconductor dies and a plurality of signal lines that communicatively couple the controller to the stack of semiconductor dies. The semiconductor package also includes electrical stress detection circuitry within each semiconductor die in the stack of semiconductor dies. The electrical stress detection circuitry is also communicatively coupled to the plurality of signal lines. In an example, the controller is configured to transmit a test voltage to the electrical stress detection circuitry and cause the electrical stress detection circuitry to compare the test voltage to at least one of a first threshold voltage associated with an overshoot value and a second threshold voltage associated with an undershoot value on a particular signal line of the plurality of signal lines. The controller is also configured to receive a result of the comparison.

Still other examples describe a semiconductor package that includes a controller means, a stack of semiconductor dies and a plurality of signal means communicatively coupling the controller means to the stack of semiconductor dies. The semiconductor package also includes electrical stress detection means. The electrical stress detection means is included with at least one semiconductor die in the stack of semiconductor dies. The electrical stress detection means is also communicatively coupled to the plurality of signal means. In an example, the electrical stress detection means is configured to receive a test voltage and compare the test voltage to at least one of a first threshold voltage associated with an overshoot value and a second threshold voltage associated with an undershoot value on a particular signal line of the plurality of signal means. The electrical stress detection means also provides a result of the comparison to the controller means.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 is a block diagram of a system that includes a host device and a data storage device according to an example.

FIG. 2 illustrates a semiconductor package having electrical stress detection circuitry according to an example.

FIG. 3 illustrates a semiconductor package having electrical stress detection circuitry according to another example.

FIG. 4 illustrates a method for determining whether a semiconductor die is subject to electrical stresses, such as an undershoot and/or an overshoot, according to an example.

FIG. 5 illustrates a method for determining whether a semiconductor die is subject to electrical stresses, such as an undershoot and/or an overshoot, according to another example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. Examples may be practiced as methods, systems or devices. Accordingly, examples may take the form of a hardware implementation, an entirely software implementation, or an implementation combining software and hardware aspects. The following detailed description is therefore not to be taken in a limiting sense, and the scope of the present disclosure is defined by the appended claims and their equivalents.

As previously described, a lifespan of integrated circuits and semiconductor packages can be affected by various electrical stresses. Some of these electrical stresses include phenomenon known as overshoot and undershoot. An overshoot occurs when a voltage of a signal exceeds a desired amplitude. Likewise, an undershoot occurs when the voltage of a signal falls below a desired amplitude.

In current solutions, the amplitude of a signal is detected at a test point, or a test pad, of the semiconductor package. Typically, the test point is located some distance away from input/output (I/O) pads of one or more semiconductor dies of the semiconductor package. However, the characteristics of the signal received by the one or more semiconductor dies is dependent on multiple parameters. These parameters include, but not limited to, driver impedance, the printed circuit board (PCB) and/or packaging channel, parasitic and/or impedance factors, a load of the semiconductor dies and so on. Thus, as the signal is transmitted from the test pad and/or across the PCB, a measurement of the signal may be inaccurate. As a result, overshoot and/or undershoot may go undetected.

To address the above, the present disclosure describes electrical stress detection circuitry (also referred to a swing level detector) for a semiconductor package. The electrical stress detection circuitry is located within, or proximate to, one or more semiconductor dies of the semiconductor package. The electrical stress detection circuitry is also electrically coupled to one or more input/output lines, or signal lines, of the semiconductor package. For example, the electrical stress detection circuitry is coupled to one or more input/output (I/O) lines that extend between a transmitter (e.g., a controller) associated with the semiconductor package and one or more receivers (e.g., semiconductor dies) of the semiconductor package. Because the electrical stress detection circuitry is located proximate to or within the receiver, the electrical stress detection circuitry can more accurately detect overshoot and/or undershoot when compared with current solutions.

For example, when testing for overshoot and/or undershoot, a test signal or a test voltage is provided, from the controller, to a selected semiconductor die. Because the electrical stress detection circuitry is coupled to the signal line associated with the selected semiconductor die, the electrical stress detection circuitry also receives the test voltage.

When the test voltage is received, the electrical stress detection circuitry compares the test voltage to a configurable threshold voltage. In an example, the configurable threshold voltage is a first threshold voltage associated with an overshoot value. In another example, the configurable threshold voltage is a second threshold voltage associated with an undershoot value. When the comparison is complete, the electrical stress detection circuitry provides feedback to the controller. The feedback indicates whether the voltage of the received signal exceeds one or more of the thresholds.

In an example, the transmitter/controller can cause the electrical stress detection circuitry to toggle or switch between the various I/O lines or signal lines that are coupled to one or more of the receivers. As such, the electrical stress detection circuitry test/compare various signals on a number of different signal lines.

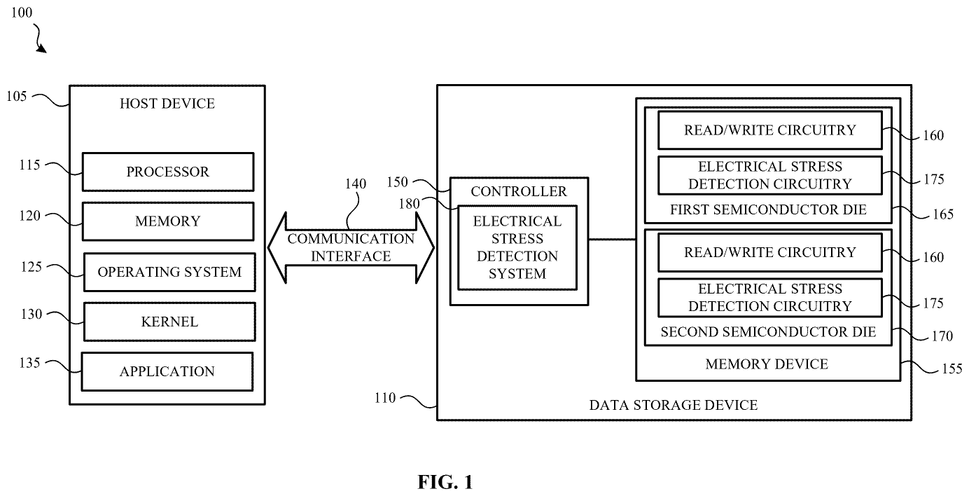

Accordingly, many technical benefits may be realized including, but not limited to, increasing the accuracy of detection of electrical stresses that are imposed on semiconductor devices, enabling individual semiconductor die validation in stacked semiconductor die implementations, and providing insight on the reliability of signal/transmission lines which may increase the overall lifespan of the semiconductor device. These and other examples will be described in more detail with respect to FIG. 1-FIG. 5.

FIG. 1 is a block diagram of a system 100 that includes a host device 105 and a data storage device 110 according to an example. Although a data storage device 110 is specifically mentioned, the data storage device 110 may be any type of semiconductor package that includes one or more semiconductor dies.

In an example, the host device 105 includes a processor 115 and a memory 120 (e.g., main memory). The memory 120 includes or is otherwise associated with an operating system 125, a kernel 130 and/or an application 135.

The processor 115 can execute various instructions, such as, for example, instructions from the operating system 125 and/or the application 135. The processor 115 includes circuitry such as a microcontroller, a Digital Signal Processor (DSP), an Application-Specific Integrated Circuit (ASIC), a Field Programmable Gate Array (FPGA), hard-wired logic, analog circuitry and/or various combinations thereof. In an example, the processor 115 includes a System on a Chip (SoC).

In an example, the memory 120 is used by the host device 105 to store data used, or otherwise executed by, the processor 115. Data stored in the memory 120 includes instructions provided by the data storage device 110 via a communication interface 140. The data stored in the memory 120 also includes data used to execute instructions from the operating system 125 and/or one or more applications 135. The memory 120 may be a single memory or may include multiple memories, such as, for example one or more non-volatile memories, one or more volatile memories, or a combination thereof.

In an example, the operating system 125 creates a virtual address space for the application 135 and/or other processes executed by the processor 115. The virtual address space maps to locations in the memory 120. The operating system 125 also includes or is otherwise associated with a kernel 130. The kernel 130 includes instructions for managing various resources of the host device 105 (e.g., memory allocation), handling read and write requests and so on.

The communication interface 140 communicatively couples the host device 105 and the data storage device 110. The communication interface 140 may be a Serial Advanced Technology Attachment (SATA), a PCI express (PCIe) bus, a Small Computer System Interface (SCSI), a Serial Attached SCSI (SAS), Ethernet, Fibre Channel, or Wi-Fi. As such, the host device 105 and the data storage device 110 need not be physically co-located and may communicate over a network such as a Local Area Network (LAN) or a Wide Area Network (WAN), such as the internet. In addition, the host device 105 may interface with the data storage device 110 using a logical interface specification such as Non-Volatile Memory express (NVMe) or Advanced Host Controller Interface (AHCI).

The data storage device 110 includes a controller 150 and a memory device 155. Although a memory device 155 is specifically mentioned, the memory device 155 may be any type of computing device or semiconductor package. In an example, the controller 150 is communicatively coupled to the memory device 155 using one or more signal/communication lines (e.g., an input/output (I/O) bus). The memory device 155 includes one or more semiconductor dies (e.g., a first semiconductor die 165 and a second semiconductor die 170). In an example, the semiconductor dies are memory dies. Although memory dies are specifically mentioned, the memory device 155 may include any non-volatile memory device, storage device, storage elements or storage medium including NAND flash memory cells and/or NOR flash memory cells.

The memory cells can take the form of solid-state (e.g., flash) memory cells and can be one-time programmable, few-time programmable, or many-time programmable. Additionally, the memory cells may be single-level cells (SLCs), multi-level cells (MLCs), triple-level cells (TLCs), quad-level cells (QLCs), penta-level cells (PLCs), and/or use any other memory technologies. In one example, the memory cells are arranged in a two-dimensional configuration. In another example, the memory cells are arranged in a three-dimensional configuration.

In an example, the data storage device 110 is attached to or embedded within the host device 105. In another example, the data storage device 110 is implemented as an external device or a portable device that can be communicatively or selectively coupled to, and removed from, the host device 105. In yet another example, the data storage device 110 is a component (e.g., a solid-state drive (SSD)) of a network accessible data storage system, a network-attached storage system, a cloud data storage system, or the like.

As indicated above, the memory device 155 of the data storage device 110 includes a first semiconductor die 165 and a second semiconductor die 170. Although two semiconductor dies are shown, the memory device 155 may include any number of semiconductor dies (e.g., one semiconductor die, two semiconductor dies, eight semiconductor dies, or another number of semiconductor dies).

The memory device 155 also includes support circuitry. For example, each semiconductor dies includes read/write circuitry 160. The read/write circuitry 160 supports the operation of the semiconductor dies of the memory device 155. Although the read/write circuitry 160 is depicted as a single component, the read/write circuitry 160 may be divided into separate components, such as, for example, read circuitry and write circuitry. As shown in FIG. 1, one or more of the semiconductor dies includes corresponding read/write circuitry 160 that is operable to read data from and/or write data to storage elements within one individual semiconductor die independent of other read and/or write operations on any of the other semiconductor dies. In another example, the read/write circuitry 160 may be external to the semiconductor dies of the memory device 155.

In an example, one or more of the first semiconductor die 165 and the second semiconductor die 170 include one or more memory blocks and each memory block includes one or more memory cells. A block of memory cells is the smallest number of memory cells that are physically erasable together. In an example and for increased parallelism, each of the blocks may be operated or organized in larger blocks or metablocks. For example, one block from different memory dies may be logically linked together to form a metablock.

Each of the first semiconductor die 165 and the second semiconductor die 170 also include electrical stress detection circuitry 175. In an example, the electrical stress detection circuitry 175 is connected to the various signal/communication lines that communicatively couple the semiconductor dies of the memory device 155 to the controller 150. The electrical stress detection circuitry 175 is operable to receive and/or sense a test voltage that is transmitted from the controller 150 to the semiconductor dies using the various signal/communication lines. When the test voltage is received/sensed, the electrical stress detection circuitry 175 determines whether the signal line(s) is subject to an overshoot and/or an undershoot.

As previously discussed, an overshoot occurs when a voltage of a signal exceeds a desired amplitude (e.g., 1.2 volts (V)). Likewise, an undershoot occurs when the voltage of a signal falls below a desired amplitude (e.g., −0.3 V). As such, the electrical stress detection circuitry 175 is programmed to detect whether an overshoot and/or an undershoot is occurring on various signal/communications lines of the data storage device 110.

For example, the electrical stress detection circuitry 175 stores, or otherwise receives, a threshold voltage. In an example, the threshold voltage is received from the controller 150. Additionally, the threshold voltage is programmable and can be used to detect an overshoot or an undershoot on one or more of the signal/communication lines. For example, when detecting whether an overshoot exists on the one or more signal/communication lines, the threshold voltage is set at 1.2V. In another example, the threshold voltage is set at 1.8V. Likewise, when detecting whether an undershoot exists on one or more of the signal/communication lines, the threshold voltage is set at −0.3V. Although specific voltages are given, the electrical stress detection circuitry 175 can be programmed to have any desired threshold voltage.

After the threshold voltage has been programmed or set, the electrical stress detection circuitry 175 receives information about a particular signal line and/or semiconductor die to test for the overshoot and/or the undershoot. The electrical stress detection circuitry also receives a test voltage. In an example, the information regarding the particular semiconductor die and/or signal line, as well as the test voltage, is received from the controller 150 and/or an electrical stress detection system 180 associated with the controller 150.

In response to receiving the test voltage, the electrical stress detection circuitry 175 compares the test voltage to the threshold voltage. If the test voltage exceeds (e.g., overshoots or undershoots) the threshold voltage, an output of a comparator associated with the electrical stress detection circuitry 175 is set to “high” (or to another value indicating that the threshold voltage was exceeded). Otherwise, the output of the comparator associated with the electrical stress detection circuitry is set to “low” (or to another value indicating that the threshold voltage was not exceeded). The output is then provided to the controller 150.

In an example, when the controller 150 receives the output that indicates whether an overshoot and/or an undershoot was detected, the controller 150 stores the information. Additionally, the controller 150 may take corrective steps and/or use the received information to determine how to the overcome the overshoot and/or undershoot on a signal/communication line on which the overshoot and/or undershoot was detected.

In an example, the electrical stress detection circuitry 175 is operable to detect overshoot and/or undershoot on a number of different signal lines - each of which may be connected to the same semiconductor dies or different semiconductor dies. For example, the electrical stress detection circuitry 175 is communicatively coupled to a number of different signal lines and sweeps or tests each signal line for an overshoot or undershoot.

In an example, the signal lines are associated with different semiconductor dies of the memory device. For example a first signal line is associated with the first semiconductor die 165 and a semiconductor signal line is associated with a second semiconductor die 170 that is stacked on top of the first semiconductor die 165. Based on a received command (e.g., from the controller 150), the electrical stress detection circuitry 175 can switch or toggle between receiving test voltages on the signal line associated with the first semiconductor die 165 and the signal line associated with the second semiconductor die 170. In another example, the controller 150 toggles between different electrical stress detection circuitry 175. For example, the controller 150 may send a test signal to electrical stress detection circuitry 175 associated with the first semiconductor die 165 and then send a test signal to electrical stress detection circuitry 175 associated with the second semiconductor die 170.

Additionally, the electrical stress detection circuitry 175 can toggle between detecting for an overshoot and detecting for an undershoot. For example, the controller 150 can program or otherwise cause the electrical stress detection circuitry 175 to compare the test voltage to a first threshold voltage associated with an overshoot value. The controller 150 also programs or causes the electrical stress detection circuitry 175 to compare the test voltage to a second threshold voltage associated with an undershoot value.

In an example, the controller 150 causes the electrical stress detection circuitry 175 to test each signal/communication line for an overshoot (or an undershoot). When all of the signal/communication lines have been checked for an overshoot, the controller 150 causes the electrical stress detection circuitry 175 to test for an undershoot (or an overshoot if the electrical stress detection circuitry 175 previously monitored the signal/communication lines for an undershoot).

As previously described, the data storage device 110 also includes a controller 150. Although a single controller 150 is shown and described, the data storage device 110 can include multiple controllers. In such an example, a first controller executes a first operation or set of operations and the second controller executes a second operation or set of operations. In an example, the first set of operations and the second set of operations are executed on the same semiconductor dies. In other examples, the first set of operations is executed on the first semiconductor die 165, or a first set of semiconductor dies, and the second set of operations is executed on the second semiconductor die 170, or a second set of semiconductor dies.

The controller 150 is communicatively coupled to the memory device 155 via an input/output (I/O) bus, an interface or other communication circuitry. In an example, the communication circuitry includes one or more channels to enable the controller 150 to communicate with the first semiconductor die 165 and/or the second semiconductor die 170 of the memory device 155. In another example, the communication circuitry includes multiple distinct channels which enables the controller 150 to communicate with the first semiconductor die 165 independently and/or in parallel with the second semiconductor die 170 of the memory device 155.

The controller 150 receives data and/or instructions from the host device 105. The controller 150 also sends data to the host device 105. For example, the controller 150 sends data to and/or receives data from the host device 105 via the communication interface 140. The controller 150 also sends data and/or commands to, and/or receive data from, the memory device 155.

The controller 150 sends data and a corresponding write command to the memory device 155 to cause the memory device 155 to store data at a specified address of the memory device 155. In an example, the write command specifies a physical address of a portion of the memory device 155. The controller 150 also sends one or more read commands to the memory device 155. In an example, the read command specifies the physical address of a portion of the memory device 155 at which the data is stored.

As previously described, the controller 150 also includes, or is otherwise associated with, an electrical stress detection system 180. In an example, the electrical stress detection system 180 is a packaged functional hardware unit designed for use with other components/systems. In another example, the electrical stress detection system 180 is a portion of a program code (e.g., software or firmware) executable by a processor or processing circuitry. In yet another example, the electrical stress detection system 180 is a self-contained hardware and/or software component/system that interfaces with other components and/or systems. Although the electrical stress detection system 180 is shown as being part of the controller 150, the electrical stress detection system 180 may be separate from the controller 150.

In an example, the electrical stress detection system 180 is operable to send commands and/or instructions to the electrical stress detection circuitry 175 associated with the memory device 155 such as previously described. The electrical stress detection system 180 is also operable to receive information (e.g., whether an undershoot or overshoot was detected on a particular signal line) from the electrical stress detection circuitry 175.

For example, the electrical stress detection system 180 programs or sets a voltage level of the test voltage that is provided to the electrical stress detection circuitry 175. In another example, the electrical stress detection system 180 programs or sets the threshold voltage associated with the overshoot value and/or the threshold voltage associated with the undershoot value.

The electrical stress detection system 180 also selects which semiconductor die and/or signal/communications lines that will be tested for an undershoot and/or an overshoot. For example, the electrical stress detection system 180 may send a byte address to the electrical stress detection circuitry 175 associated with a particular semiconductor die to indicate that the particular semiconductor die and signal/communication line(s) associated with the particular semiconductor die are to be tested. The electrical stress detection system 180 may also continuously select or toggle one, some or all of the signal/communications lines (e.g., DQS, BDQS, FD Bus, RE, and Ren I/O lines) associated with the particular semiconductor die.

As previously discussed, the electrical stress detection system 180 may also toggle between detecting or testing for an overshoot and/or detecting and/or testing for an undershoot. For example, the electrical stress detection system 180 may send a command to the memory device 155 and/or the electrical stress detection circuitry 175 associated with a particular semiconductor die to test for overshoot or to test for an undershoot.

In an example, and in order to ensure the comparison executed by the electrical stress detection circuitry 175 is as accurate as possible, the electrical stress detection system 180 toggles a ready/busy signal associated with a signal line to select a semiconductor die of interest and ensure that no operations are being executed on unselected semiconductor dies. For example, the electrical stress detection system 180 toggles a ready/busy signal to “low” to prevent other operations from being performed on the unselected semiconductor dies.

The electrical stress detection system 180 sends or transmits the test voltage to the selected semiconductor die over one or more signal/communications lines. In response to the electrical stress detection circuitry 175 completing the comparison between the test voltage and the threshold voltage, the electrical stress detection system 180 receives the result of the comparison such as previously described. For example, if an overshoot or an undershoot is detected, the electrical stress detection system 180 receives a first indication. However, if an overshoot or an undershoot is not detected, the electrical stress detection system 180 receives a second indication.

In an example, the indicators received from the electrical stress detection circuitry 175 are stored by the electrical stress detection system 180. For example, the indicators are stored in one or more read/write special function registers. In one example, different special function registers are used to store data associated with different signal/communication lines. The electrical stress detection system 180 can also receive an indication (e.g., from the electrical stress detection circuitry 175) as to whether the comparison between the signal voltage and one or more of the threshold voltages was executed completely and/or correctly. If the comparison was not correctly completed, the electrical stress detection system 180 sends another test voltage to the particular semiconductor die and/or the electrical stress detection circuitry 175 associated with the particular semiconductor die and causes the electrical stress detection circuitry 175 to execute the comparison a second time.

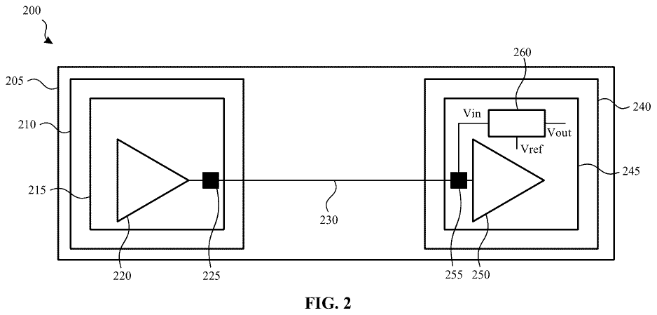

FIG. 2 illustrates a semiconductor package 200 having electrical stress detection circuitry 260 according to an example. In an example, the semiconductor package 200 includes various semiconductor dies and may be arranged in a 2D package configuration, a 2.5D through silicon via (TSV) configuration and/or a 3D TSV configuration. Although specific configurations are mentioned, the semiconductor package 200 may be arranged in any suitable configuration. In an example, the semiconductor package 200 is similar to, or has similar components and/or systems with, the data storage device 110 shown and described with respect to FIG. 1.

In this example, the semiconductor package 200 includes a transmitter 220. In an example, the transmitter 220 is similar to the controller 150 shown and described with respect to FIG. 1. The transmitter 220 is provided on a substrate 215 and may also be encapsulated by packaging 210 which is mounted on, or otherwise coupled to, a printed circuit board (PCB) 205.

The semiconductor package 200 also includes a receiver 250. In an example, the receiver 250 is a semiconductor die or a memory die. For example, the receiver 250 is similar to the first semiconductor die 165 and/or the second semiconductor die 170 shown and described with respect to FIG. 1. Although a single receiver 250 or semiconductor die is shown, the semiconductor package 200 can include multiple receivers 250 or semiconductor dies. In examples in which multiple receivers 250 are present, the receivers 250 are positioned on top of each other to form a stack (e.g., a stack of semiconductor dies). Like the transmitter 220, the receiver 250 is provided on a substrate 240, is encapsulated by packaging 245 and mounted on the PCB 205.

One or more signal lines 230 (or I/O lines) extend between the transmitter 220 and the receiver 250. For example, a signal line 230 extends from the transmitter 220 to a first pad 225 associated with the transmitter 220. The signal line 230 also extends across the PCB 205 to a second pad 255 associated with the receiver 250. The signal line 230 is also coupled to the receiver 250.

The semiconductor package 200 also includes electrical stress detection circuitry 260. As shown in FIG. 2, the electrical stress detection circuitry 260 is located proximate to, or within the receiver 250. For example, the electrical stress detection circuitry 260 is encapsulated by the same packaging 245 that encapsulates the receiver 250. In another example, the electrical stress detection circuitry 260 is located outside of the packaging 245 but is provided on the same substrate 240 as the receiver 250. The electrical stress detection circuitry 260 is also coupled to the signal line 230 (e.g., via the second pad 255). As a result, the electrical stress detection circuitry 260 can sense and/or receive any signals that are provided to the receiver 250.

In an example, the transmitter 220 provides a reference voltage to the electrical stress detection circuitry 260. The reference voltage (represented as “Vref”) is a programmable value that is used to determine whether the signal line 230 is subject to an overshoot and/or an undershoot. For example, the reference voltage may be set to a first threshold voltage when detecting an overshoot and a second threshold voltage when detecting an undershoot.

The electrical stress detection circuitry 260 receives or senses a test voltage from the transmitter 220. For example, the transmitter 220 transmits a test voltage on the signal line 230 to the receiver 250. Because the electrical stress detection circuitry 260 is coupled to the signal line 230 (e.g., via the second pad 255), the electrical stress detection circuitry 260 also receives or senses the test voltage via an input pin “Vin”. In response to receiving the test voltage, the electrical stress detection circuitry compares the test voltage to the reference voltage Vref.

If the electrical stress detection circuitry 260 determines that the test voltage exceeds (e.g., overshoots or undershoots) the threshold voltage Vref, an output pin (e.g., “Vout”) of a comparator of the electrical stress detection circuitry 260 is set to a particular value to indicate that an undershoot/overshoot is detected. For example, if the electrical stress detection circuitry 260 determines that an overshoot and/or an undershoot is detected, a comparator associated with the electrical stress detection circuitry 260 is set to “high” (or to another value indicating that the threshold voltage was exceeded). Otherwise, the output of the comparator associated with the electrical stress detection circuitry 260 is set to “low” (or to another value indicating that the threshold voltage was not exceeded). The output/feedback is then provided, via the signal line 230 (or other signal line), back to the transmitter 220.

In an example, when the transmitter 220 receives the feedback that indicates whether an overshoot and/or an undershoot was detected, the transmitter 220 stores the information. Additionally, the transmitter 220 may take corrective steps and/or use the received information to determine how to the overcome the overshoot and/or undershoot on a signal/communication line on which the overshoot and/or undershoot was detected.

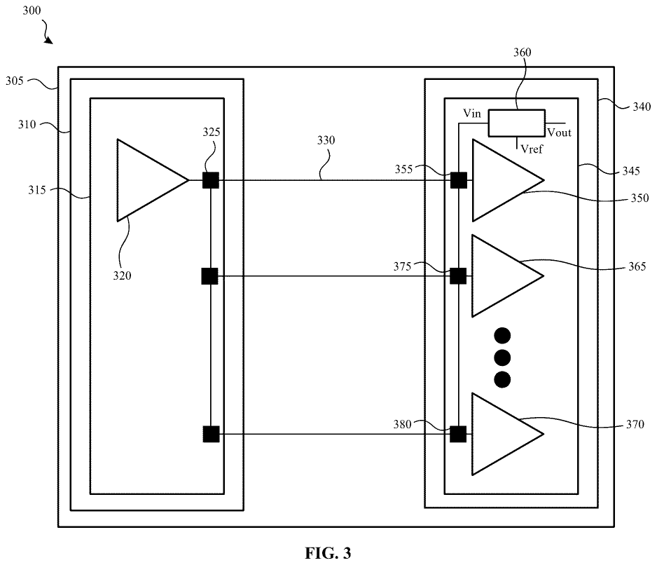

FIG. 3 illustrates a semiconductor package 300 having electrical stress detection circuitry 360 according to another example. In an example, the semiconductor package 300 is similar to the semiconductor package 200 shown and described with respect to FIG. 2.

For example, the semiconductor package 300 includes a transmitter 320 provided on a substrate 310 and encapsulated with the packaging 315 (although this is not required). The substrate 310 is provided on, or coupled to, a PCB 305.

The semiconductor package 300 also includes multiple receivers or semiconductor dies. For example, the semiconductor package 300 includes a first receiver 350, a second receiver 365 and an nth receiver 370. In an example, the receivers are stacked on top of each other and are coupled to a substrate 340 using various bond wires or other signal lines. Electrical stress detection circuitry 360 is located proximate to the receivers. For example, the electrical stress detection circuitry 360 is located on the same substrate 340 as the receivers and/or is included in packaging 345 that encapsulates the receivers. In an example, each receiver includes or is otherwise associated with its own electrical stress detection circuitry 360.

Multiple signal lines 330 extend between the transmitter 320 and the receivers. For example, a first signal line extends from the transmitter 320 to a first pad 325 and from the first pad to a second pad 355 associated with the first receiver 350. A second signal line (or the same signal line) also extends between the transmitter 320 and the second receiver 365 via a third pad 375. Likewise, a third signal line (or the same signal line) extends between the transmitter 320 and the nth receiver 370 using a nth pad 380.

As shown in FIG. 3, the electrical stress detection circuitry 360 is coupled to each pad and/or signal line associated with each receiver. As such, the electrical stress detection circuitry 360 can test for overshoot and/or undershoot on each signal line associated with each of the receivers. For example, the transmitter 320 provides instructions to the electrical stress detection circuitry 360 to test for overshoot on the signal line associated with the first receiver 350.

A test voltage is provided to the first receiver 350 and the electrical stress detection circuitry 360 senses the test voltage and compares the test volage to a reference voltage such as previously described. When the comparison is complete, the electrical stress detection circuitry 360 provides results of the comparison back to the transmitter 320. The transmitter 320 may then provide instructions to the electrical stress detection circuitry 360 to test for overshoot and/or undershoot on the second receiver 365. As such, the electrical stress detection circuitry 360 accesses the third pad 375 associated with the second receiver 365.

The transmitter 320 provides the test signal to the second receiver 365 via a signal line and the third pad 375. Because the electrical stress detection circuitry 360 is coupled to the third pad 375, the electrical stress detection circuitry 360 compares the test voltage to the threshold voltage such as previously described. This process is repeated for each of the n receivers and feedback is provided to the transmitter 320 such as previously described.

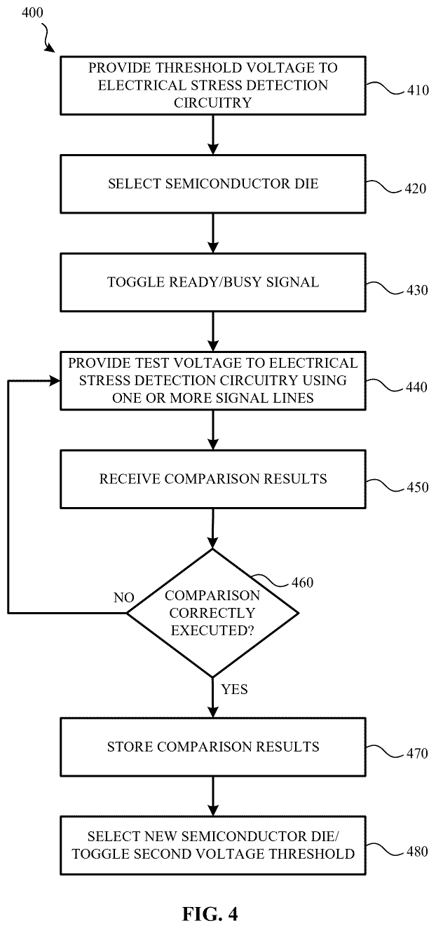

FIG. 4 illustrates a method 400 for determining whether a semiconductor die is subject to electrical stresses, such as an undershoot and/or an overshoot, according to an example. In an example, the method 400 is performed by a controller and/or an electrical stress detection system such as, for example, the controller 150 and/or the electrical stress detection system 180 shown and described with respect to FIG. 1.

In an example, the method 400 begins when the electrical stress detection system provides (410) a threshold voltage to electrical stress detection circuitry associated with a semiconductor package. In one example, the threshold voltage is associated with an undershoot value. In another example, the threshold voltage is associated with an overshoot value.

When the threshold voltage has been provided to the electrical stress detection circuitry, the electrical stress detection system selects (420) a semiconductor die and/or a signal line associated with a semiconductor die that will be tested for an undershoot and/or an overshoot. For example, the electrical stress detection system sends a byte address associated with a particular semiconductor die to the electrical stress detection circuitry to indicate that the semiconductor die (and a signal/communication line(s) associated with the semiconductor die) are to be tested.

The electrical stress detection system also toggles (430) a ready/busy signal associated with a selected signal line to select the semiconductor die of interest and ensure that operations are not being executed on unselected semiconductor dies. For example, the electrical stress detection system toggles a ready/busy signal to “low” to prevent other operations from being performed on any unselected semiconductor dies. The electrical stress detection system also provides (440) the test voltage to the electrical stress detection circuitry using one or more signal lines associated with the selected semiconductor die.

When the test voltage is received, the electrical stress detection circuitry compares the test voltage to the reference voltage and provides the results to the electrical stress detection system. In response to receiving (450) the results of the comparison, the electrical stress detection system determines (460) whether the comparison was correctly executed. If the electrical stress detection system determines the comparison between the test voltage and the threshold voltage was not executed correctly, the test voltage is provided (440) to the electrical stress detection circuitry a second time and the operations are repeated.

However, if the electrical stress detection system determines (460) the comparison between the test voltage and the reference voltage was correctly executed, the electrical stress detection system stores (470) the comparison results. The electrical stress detection system may also select (480) a new semiconductor die and/or signal line to test and/or toggle between checking the semiconductor die/signal line for an overshoot or an undershoot (depending on whether the threshold voltage received in operation 410 was associated with an overshoot value or an undershoot value). The method 400 may then be repeated.

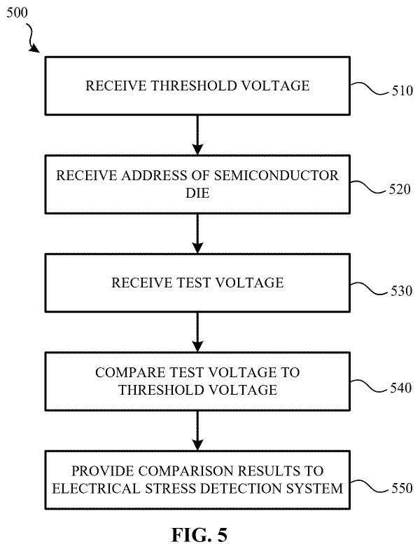

FIG. 5 illustrates a method 500 for determining whether a semiconductor die is subject to electrical stresses, such as an undershoot and/or an overshoot, according to another example. In an example, the method 500 is executed by electrical stress detection circuitry, such as, for example, electrical stress detection circuitry 175 shown and described with respect to FIG. 1.

The method 500 begins when the electrical stress detection circuitry receives (510) and/or stores a threshold voltage. In an example, the threshold voltage is provided by a controller and/or an electrical stress detection system associated with the controller. Additionally, the threshold voltage is associated with an overshoot or an undershoot. For example, if an overshoot is to be detected, the threshold voltage is a first value (e.g., 1.2V). Likewise, when an undershoot is to be detected, the threshold voltage is a second value (e.g., −0.3V). Although specific voltages are given, the threshold voltage may be any desired value.

After the threshold voltage has been received, the electrical stress detection circuitry receives (520) an address of a semiconductor die that will be tested. In response to receiving the address, the electrical stress detection circuitry accesses a signal line and/or pad associated with the particular semiconductor die and/or address and receives (530) or senses a test voltage. In an example, the test voltage is received, from the electrical stress detection system, over one or more signal lines associated with the particular semiconductor die.

In response to receiving the test voltage, the electrical stress detection circuitry compares (540) the test voltage to the threshold voltage. The electrical stress detection circuitry then provides (550) the comparison results to the electrical stress detection system.

In an example, if the test voltage exceeds (e.g., overshoots or undershoots) the threshold voltage, an output of a comparator associated with the electrical stress detection circuitry is set to “high” (or to another value indicating that the threshold voltage was exceeded). Otherwise, the output of the comparator associated with the electrical stress detection circuitry is set to “low” (or to another value indicating that the threshold voltage was not exceeded).

The method 500 may then be repeated - either for another semiconductor die, signal line, and/or for detection of an undershoot (if the method 500 was previously used to detect an overshoot and vice versa).

Based on the above, examples of the present disclosure describe a method for measuring electrical stress of a semiconductor package, comprising: transmitting a test voltage to a swing level detector included within a semiconductor die in a stack of semiconductor dies and electrically coupled to a plurality of signal lines associated with the stack of semiconductor dies; causing the swing level detector to compare the test voltage to at least one of a first threshold voltage associated with an overshoot value and a second threshold voltage associated with an undershoot value on a particular signal line of the plurality of signal lines; and receiving a result of the comparison. In an example, the method also includes receiving an indication as to whether the comparison was correctly executed. In an example, the method also includes storing the result of the comparison responsive to receiving the indication that the comparison was correctly executed. In an example, the method also includes causing the swing level detector to compare the test voltage to at least one of a first threshold voltage associated with an overshoot value and a second threshold voltage associated with an undershoot value on a particular signal line of the plurality of signal lines a second time responsive to receiving an indication the comparison was incorrectly executed. In an example, the particular signal line is a first signal line and the method further comprises: selecting a second signal line; and causing the swing level detector to compare the test voltage to at least one of the first threshold voltage associated with an overshoot value and the second threshold voltage associated with an undershoot value on the second signal line of the plurality of signal lines. In an example, the method also includes setting the first threshold voltage associated with the overshoot value and the second threshold voltage associated with the undershoot value. In an example, the method also includes selecting a particular semiconductor die from the stack of semiconductor dies; and performing the comparison on the particular signal line of the plurality of signal lines associated with the particular semiconductor die. In an example, the method also includes toggling between comparing the test voltage to the first threshold voltage associated with the overshoot value and comparing the test voltage to the second threshold voltage associated with the undershoot value. In an example, the method also includes restricting other operations from being transmitted to other semiconductor dies in the stack of semiconductor dies.

Examples also describe a semiconductor package, comprising: a controller; a stack of semiconductor dies; a plurality of signal lines communicatively coupling the controller to the stack of semiconductor dies; and electrical stress detection circuitry within each semiconductor die in the stack of semiconductor dies and communicatively coupled to the plurality of signal lines, wherein the controller is configured to: transmit a test voltage to the electrical stress detection circuitry associated with at least one semiconductor die; cause the electrical stress detection circuitry to compare the test voltage to at least one of a first threshold voltage associated with an overshoot value and a second threshold voltage associated with an undershoot value on a particular signal line of the plurality of signal lines; and receive a result of the comparison. In an example, the controller is further configured to receive an indication as to whether the comparison was correctly executed. In an example, the controller is further configured to store the result of the comparison responsive to receiving the indication that the comparison was correctly executed. In an example, the controller is further configured to cause the electrical stress detection circuitry to compare the test voltage to at least one of a first threshold voltage associated with an overshoot value and a second threshold voltage associated with an undershoot value on a particular signal line of the plurality of signal lines a second time responsive to receiving an indication the comparison was incorrectly executed. In an example, the particular signal line is a first signal line and the controller is further configured to: select a second signal line; and cause the electrical stress detection circuitry to compare the test voltage to at least one of the first threshold voltage associated with an overshoot value and the second threshold voltage associated with an undershoot value on the second signal line of the plurality of signal lines. In an example, the controller is further configured to set the first threshold voltage associated with the overshoot value and the second threshold voltage associated with the undershoot value. In an example, the controller is further configured to: select a particular semiconductor die from the stack of semiconductor dies; and perform the comparison on the particular signal line of the plurality of signal lines associated with the particular semiconductor die. In an example, the controller is further configured to switch between comparing the test voltage to the first threshold voltage associated with the overshoot value and comparing the test voltage to the second threshold voltage associated with the undershoot value.

Examples also describe a semiconductor package, comprising: a controller means; a stack of semiconductor dies; a plurality of signal means communicatively coupling the controller means to the stack of semiconductor dies; and electrical stress detection means associated with each semiconductor die in the stack of semiconductor dies and communicatively coupled to the plurality of signal means, the electrical stress detection means configured to: receive a test voltage; compare the test voltage to at least one of a first threshold voltage associated with an overshoot value and a second threshold voltage associated with an undershoot value on a particular signal line of the plurality of signal means; and provide a result of the comparison to the controller means. In an example, the electrical stress detection means selects another signal line of the plurality of signal means on which to compare the test voltage to the at least the one of the first threshold voltage associated with the overshoot value and the second threshold voltage associated with the undershoot value. In an example, the electrical stress detection means selects the another signal line of the plurality of signal means based, at least in part, on a signal received from the controller means.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A method for measuring electrical stress of a semiconductor package, comprising:
transmitting a test voltage to a swing level detector included within a semiconductor die in a stack of semiconductor dies and electrically coupled to a plurality of signal lines associated with the stack of semiconductor dies;
causing the swing level detector to compare the test voltage to at least one of a first threshold voltage associated with an overshoot value and a second threshold voltage associated with an undershoot value on a particular signal line of the plurality of signal lines; and
receiving a result of the comparison.

2. The method of claim 1, further comprising receiving an indication as to whether the comparison was correctly executed.

3. The method of claim 2, further comprising storing the result of the comparison responsive to receiving the indication that the comparison was correctly executed.

4. The method of claim 2, further comprising causing the swing level detector to compare the test voltage to at least one of a first threshold voltage associated with an overshoot value and a second threshold voltage associated with an undershoot value on a particular signal line of the plurality of signal lines a second time responsive to receiving an indication the comparison was incorrectly executed.

5. The method of claim 1, wherein the particular signal line is a first signal line and the method further comprises:
selecting a second signal line; and
causing the swing level detector to compare the test voltage to at least one of the first threshold voltage associated with an overshoot value and the second threshold voltage associated with an undershoot value on the second signal line of the plurality of signal lines.

6. The method of claim 1, further comprising setting the first threshold voltage associated with the overshoot value and the second threshold voltage associated with the undershoot value.

7. The method of claim 1, further comprising:
selecting a particular semiconductor die from the stack of semiconductor dies; and
performing the comparison on the particular signal line of the plurality of signal lines associated with the particular semiconductor die.

8. The method of claim 1, further comprising toggling between comparing the test voltage to the first threshold voltage associated with the overshoot value and comparing the test voltage to the second threshold voltage associated with the undershoot value.

9. The method of claim 1, further comprising restricting other operations from being transmitted to other semiconductor dies in the stack of semiconductor dies.

10. A semiconductor package, comprising:
a controller;
a stack of semiconductor dies;
a plurality of signal lines communicatively coupling the controller to the stack of semiconductor dies; and
electrical stress detection circuitry within each semiconductor die in the stack of semiconductor dies and communicatively coupled to the plurality of signal lines, wherein the controller is configured to:
transmit a test voltage to the electrical stress detection circuitry associated with at least one semiconductor die;
cause the electrical stress detection circuitry to compare the test voltage to at least one of a first threshold voltage associated with an overshoot value and a second threshold voltage associated with an undershoot value on a particular signal line of the plurality of signal lines; and
receive a result of the comparison.

11. The semiconductor package of claim 10, wherein the controller is further configured to receive an indication as to whether the comparison was correctly executed.

12. The semiconductor package of claim 11, wherein the controller is further configured to store the result of the comparison responsive to receiving the indication that the comparison was correctly executed.

13. The semiconductor package of claim 11, wherein the controller is further configured to cause the electrical stress detection circuitry to compare the test voltage to at least one of a first threshold voltage associated with an overshoot value and a second threshold voltage associated with an undershoot value on a particular signal line of the plurality of signal lines a second time responsive to receiving an indication the comparison was incorrectly executed.

14. The semiconductor package of claim 10, wherein the particular signal line is a first signal line and the controller is further configured to:
select a second signal line; and
cause the electrical stress detection circuitry to compare the test voltage to at least one of the first threshold voltage associated with an overshoot value and the second threshold voltage associated with an undershoot value on the second signal line of the plurality of signal lines.

15. The semiconductor package of claim 10, wherein the controller is further configured to set the first threshold voltage associated with the overshoot value and the second threshold voltage associated with the undershoot value.

16. The semiconductor package of claim 10, wherein the controller is further configured to:
select a particular semiconductor die from the stack of semiconductor dies; and
perform the comparison on the particular signal line of the plurality of signal lines associated with the particular semiconductor die.

17. The semiconductor package of claim 10, wherein the controller is further configured to switch between comparing the test voltage to the first threshold voltage associated with the overshoot value and comparing the test voltage to the second threshold voltage associated with the undershoot value.

18. A semiconductor package, comprising:
a controller means;
a stack of semiconductor dies;
a plurality of signal means communicatively coupling the controller means to the stack of semiconductor dies; and
electrical stress detection means associated with each semiconductor die in the stack of semiconductor dies and communicatively coupled to the plurality of signal means, the electrical stress detection means configured to:
receive a test voltage;
compare the test voltage to at least one of a first threshold voltage associated with an overshoot value and a second threshold voltage associated with an undershoot value on a particular signal line of the plurality of signal means; and
provide a result of the comparison to the controller means.

19. The semiconductor package of claim 18, wherein the electrical stress detection means selects another signal line of the plurality of signal means on which to compare the test voltage to the at least the one of the first threshold voltage associated with the overshoot value and the second threshold voltage associated with the undershoot value.

20. The semiconductor package of claim 19, wherein the electrical stress detection means selects the another signal line of the plurality of signal means based, at least in part, on a signal received from the controller means.
